(19) United States
(12) Patent Application Publication
(10) Pub. No.: US 2023/0013968 A1
(43) Pub. Date: Jan. 19, 2023

(54) Light-Emitting Structure, Display Apparatus and Illuminating Apparatus

(71) Applicant: SUZHOU XINGSHUO NANOTECH CO., LTD., Suzhou, Jiangsu (CN)

(72) Inventor: Yunjun WANG, Suzhou, Jiangsu (CN)

(21) Appl. No.: 17/784,678

(22) PCT Filed: Nov. 5, 2020
(86) PCT No.: PCT/CN2020/126796

§ 371 Date: Jun. 13, 2022

(30) Foreign Application Priority Data
Dec. 13, 2019 (CN) 201911280487.2

(51) Int. Cl. H01L 51/52; H01L 27/32; H01L 51/50

(52) U.S. Cl. CPC H01L 51/5234; H01L 27/3209; H01L 51/502; H01L 2251/305

(57) ABSTRACT

Provided in embodiments of the present disclosure are a light-emitting structure, a display apparatus and an illuminating apparatus. The light-emitting structure includes at least two light-emitting layers stacked layer by layer, wherein the at least two light-emitting layers are used to emit at least two colors; and a transparent electrode, which is disposed between adjacent light-emitting layers. By means of providing the transparent electrode between adjacent light-emitting layers, the present disclosure adjusts the light colors of the light-emitting structure effectively, and improves the resolution of the light-emitting structure.

### CROSS REFERENCE TO RELATED APPLICATIONS

This application is a national application of PCT/CN2020126796, filed on Nov. 5, 2020. The contents of PCT/CN2020126796 are all hereby incorporated by reference.

### TECHNICAL FIELD

The present disclosure belongs to the field of light-emitting technology, in particular to a light-emitting structure, a display apparatus and an illuminating apparatus.

### BACKGROUND

The electroluminescent structure includes an anode, a light-emitting layer and a cathode disposed in stack. The light-emitting layer is mainly used to emit red light, green light or blue light. The electroluminescent structure synthesizes the light of the desired color by adjusting the brightness of the three light colors. At present, the light-emitting structure mainly used and existing related problems are as follows:

(1) P-N type semiconductor connected tandem laminated structure. This technology can be realized, however, due to the complex structure of that, and the mixed light color will change slightly with the voltage, it is failing to emit pure monochromatic light.

(2) Multi-light emitting layer structure. Ultra-thin spacing layers (zinc oxide, polymer, etc.) are used in the middle of each light-emitting layer. Most of the spacing layers cannot balance the hole and electron mobility, they have low luminous efficiency and small light color change range, and fail to emit pure monochromatic light.

(3) RGB pixel structure. High resolution has always been an important goal in the display field and once became an important selling point of products such as mobile phones, televisions, etc. However, the resolution improvement is limited by separating RGB three primary colors with pixels, regardless of whether evaporation technology or ink-jet printing technology is adopted.

It can be seen from the above that the existing light-emitting structure has the problems that the light color is difficult to adjust, and the display resolution is needed to be improved. It is urgent to find a light-emitting structure that can effectively adjust the light color and improve the resolution.

### SUMMARY

In order to solve the technical problems mentioned above, the present disclosure provides a light-emitting structure, the light-emitting structure includes at least two light-emitting layers stacked layer by layer, wherein the at least two layers of light-emitting layers are used to emit at least two colors; and a transparent electrode, which is disposed between the adjacent light-emitting layers.

Further, the transparent electrode is a shared cathode or a shared anode of the adjacent light-emitting layers.

Further, the light-emitting structure includes two transparent electrodes, which are anodes and/or cathodes of the adjacent light-emitting layers, respectively; preferably, a spacer is set between the two transparent electrodes; more preferably, the spacer includes a transparent adhesive layer and/or a gas area.

Further, the light-emitting structure further includes at least two control circuits, which are electrically connected with the light-emitting layers; preferably, the control circuits are arranged in one-to-one correspondence with the light-emitting layers.

Further, the light transmittance of the transparent electrode is 50% to 99.9%; preferably, the thickness of the transparent electrode is 10 nm to 100 μm; preferably, the light-emitting layer is an organic light-emitting layer and/or a quantum dot light-emitting layer.

Further, the material of the transparent electrode includes at least one of one-dimensional two-dimensional nanomaterials, two-dimensional nanomaterials, metal materials and conductive metal oxide materials; preferably, the material of the transparent electrode is selected from one or more of silver nanowires, copper nanowires, silver, graphene, indium tin oxide, element-doped zinc oxide and carbon nanotubes.

Further, the light-emitting structure includes two layers of the light-emitting layers, the two layers of the light-emitting layers emit red light and green light, respectively, or the two layers of the light-emitting layers emit red light and blue light, respectively, or the two layers of the light-emitting layers emit green light and blue light, respectively, or the two layers of the light-emitting layers emit blue light and yellow light, respectively.

Further, the light-emitting structure includes a first electrode, a first hole transport layer, a first light-emitting layer, a first electron transport layer, a transparent electrode, a second electron transport layer, a second light-emitting layer, a second hole transport layer, and a second electrode; more preferably, at least one of the light transmittances of the first electrode and the second electrode is 50% to 99.9%; more preferably, the materials of the first electrode and the second electrode are separately independently selected from at least one of one-dimensional nanomaterials, or two-dimensional nanomaterials, metal materials and conductive metal oxide materials.

Further, the light-emitting structure includes three layers of the light-emitting layers, which emit red light, green light and blue light, respectively.

Further, the light-emitting structure includes a first electrode, a first hole transport layer, a first light-emitting layer, a first electron transport layer, a first transparent electrode, a second electron transport layer, a second light-emitting layer, a second hole transport layer, a second transparent electrode, a third hole transport layer, a third light-emitting layer, a third electron transport layer and a third electrode; more preferably, at least one of the light transmittances of the first electrode and the third electrode is 50% to 99.9%; more preferably, the materials of the first electrode and the third electrode are separately independently selected from at least one of one-dimensional nanomaterials, two-dimensional nanomaterials, metal materials and conductive metal oxide materials.

Further, each of the transparent electrodes located between the adjacent light-emitting layers includes a transparent electrode I and a transparent electrode II, and the transparent electrode I and the transparent electrode II each independently serve as an anode or a cathode of the light-emitting layer adjacent thereto; preferably, a spacer is arranged between the transparent electrode I and the transparent electrode II; more preferably, the spacer comprises a transparent adhesive layer and/or a gas area.

The present disclosure also provides a display apparatus, which includes the light-emitting structure described above.

The present disclosure also provides an illuminating apparatus, which includes the light-emitting structure described above.

Beneficial effects: the embodiment of the present disclosure provides a light-emitting structure and a transparent electrode. The light-emitting structure includes at least two light-emitting layers stacked layer by layer. By arranging the transparent electrodes between the adjacent light-emitting layers, the light-emitting structure is effectively simplified, and the at least two layers of the light-emitting layers is regulated flexibly to emit light of different colors, and the different colors of light are mixed to produce various light colors. The light-emitting structure of the present disclosure can both effectively adjust the colors of light and improve the resolution, and can be used for a display apparatus and an illuminating apparatus.

### BRIEF DESCRIPTION OF THE DRAWINGS

The accompanying drawings, which form a part of the disclosure, are used to provide further understanding of the present disclosure, the illustrative embodiments of the present disclosure and the description thereof are intended to explain the present disclosure and are not intended to limit thereto inappropriately. In the drawings:

FIG. 1 is a schematic diagram of a light-emitting structure according to a first embodiment of the present disclosure;

FIG. 2 is a schematic diagram of a light-emitting structure according to a second embodiment of the present disclosure;

FIG. 3 is a schematic diagram of a light-emitting structure according to a third embodiment of the present disclosure;

FIG. 4 is a schematic diagram of a light-emitting structure according to a fourth embodiment of the present disclosure;

FIG. 5 is a schematic diagram of a light-emitting structure according to a fifth embodiment of the present disclosure;

FIG. 6 is a schematic diagram of a light-emitting structure according to a sixth embodiment of the present disclosure;

FIG. 7 is a schematic diagram of a light-emitting structure according to a seventh embodiment of the present disclosure.

In the drawings, the same reference numerals are used for the same parts, and the drawings only schematically show the embodiments of the present disclosure.

### DETAILED DESCRIPTION OF THE EMBODIMENTS

The technical solutions in the embodiments of the present disclosure will be described in detail below in combination with the embodiments of the present disclosure. It should be noted that the described embodiments are only part of the embodiments of the disclosure, not all the embodiments. Exemplary embodiments can be implemented in various forms and should not be construed as limited to the examples set forth herein; On the contrary, these embodiments are provided to make the disclosure of the present disclosure more comprehensive and complete, and fully convey the concepts of the exemplary embodiments to those skilled in the art. The features, structures, or characteristics described may be combined in any suitable manner in one or more embodiments.

In addition, the drawings are only schematic diagrams disclosed in the disclosure and are not necessarily drawn to scale. The same reference numerals in the figures represent the same or similar parts, and their repeated description will be omitted.

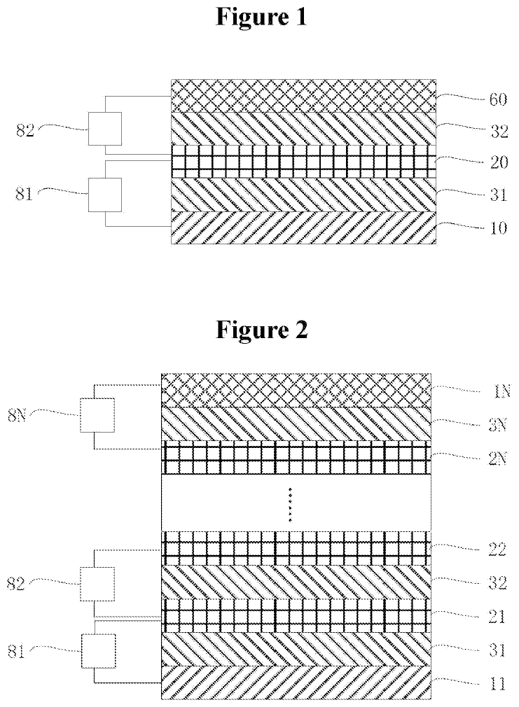

In order to solve the problems of difficulty in the adjustment of light color and low resolution in the current light-emitting structure, the present disclosure provides a light-emitting structure, such as the schematic diagram of the light-emitting structure of the first embodiment shown in FIG. 1. The light-emitting structure includes at least two light-emitting layers 31 and 32 stacked layer by layer, and the at least two layers of light-emitting layers 31 and 32 are used to emit light of at least two colors; and a transparent electrode 20, which is arranged between the adjacent light-emitting layers 31 and 32, and the transparent electrode 21 is a shared cathode or a shared anode of the adjacent light-emitting layers 31 and 32. In the embodiments of the present disclosure, by setting transparent electrodes 20 between the adjacent light-emitting layers, the light-emitting structure can flexibly regulate at least two layers of the light-emitting layers to emit light of multiple colors, and mix the light of multiple colors to obtain light of the desired color. At the same time, the resolution of the light-emitting structure is improved because the light-emitting layers emitting light of different colors are arranged longitudinally.

The above light-emitting layers in the present disclosure can realize electroluminescence through anodes and cathodes on both sides thereof. It can be understood that in addition to the transparent electrodes between the adjacent light-emitting layers, electrodes need to be set on both sides of the outermost light-emitting layer. If the transparent electrode between the outermost light-emitting layer and the adjacent light-emitting layer and close to the outermost light-emitting layer is an anode, then there is a cathode which is set at the other side of the outermost light-emitting layer; If the transparent electrode between the outermost light-emitting layer and the adjacent light-emitting layer and close to the outermost light-emitting layer is a cathode, then there is a anode which is set at the other side of the outermost light-emitting layer.

It can be understood that the light-emitting layer of the present disclosure includes at least two stacked layers, such as the second light-emitting structure shown in FIG. 2. The light-emitting structure includes the first electrode 11, the light-emitting layer 31 to the light-emitting layer 3N, the transparent electrode 21 to the transparent electrode 2N, the second electrode 1N, and the control circuit 81 to the control circuit 8N. Where N is not less than 2, and the N-layer light-emitting layer emits N colors of light. The transparent electrode can make the light of N colors of the light-emitting layer mix and emit colors, or it can also selectively emit less than N colors of mixed light as needed, or it can emit some monochromatic light as needed.

In a specific embodiment, the transparent electrode 20 of the light-emitting structure is used as the shared cathode or shared anode of the adjacent light-emitting layers 31, 32. In this disclosure, the preparation process of the light-emitting structure is greatly simplified by using the adjacent light-emitting layers as the shared cathode or shared anode, and the obtained light-emitting structure is lighter and more compact.

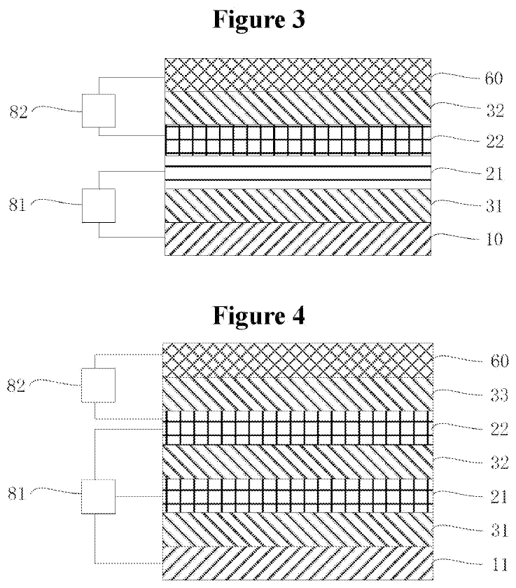

In a specific embodiment, the transparent electrode includes two transparent electrodes (transparent electrode I and transparent electrode II) located between adjacent light-emitting layers. Each transparent electrode located between the adjacent light-emitting layers includes transparent electrode I and transparent electrode II. The transparent electrode I and transparent electrode II each independently serve as the anode or cathode of the light-emitting layer adjacent thereto, such as the schematic diagram of the third light-emitting structure as shown in FIG. 3. The light-emitting structure includes an anode 10, a first light-emitting layer 31, a first transparent electrode 21, a second transparent electrode 22, a second light-emitting layer 32 and a cathode 60. The first transparent electrode 21 and the second transparent electrode 22 can be electrically connected or non-electrically connected. The light-emitting structure of the present disclosure can make the preparation of the transparent electrodes more diversified, and the transparent electrodes can be arranged in layers according to actual needs.

In a more specific embodiment, the two transparent electrodes of the light-emitting structure include a spacer. The spacer can be a transparent adhesive layer or a gas area, of course, the spacer can also be a structure which includes a transparent adhesive layer and a gas area, so as to separate the two transparent electrodes and make the two transparent electrodes act on the corresponding light-emitting layer, independently. The transparent adhesive layer is composed of an adhesive. The adhesive is used to bond the two transparent electrodes. The space between the two transparent electrodes is completely filled or partially filled, when partially filled, the unfilled space is a gas area.

There is no limitation to the materials of the transparent adhesive layer and gas area in the present disclosure, as long as the light transmittance is greater than 50%. The light-emitting structure of the present disclosure flexibly regulates the light output of the at least two layers of the light-emitting layers, and then adjusts various light colors according to needs.

In a specific embodiment, the light-emitting structure also includes at least two control circuits, and the control circuit is electrically connected with the light-emitting layer. It can be understood that the electrical connection mentioned above refers to the indirect electrical connection between the control circuit and the light-emitting layer realized through electrodes located on both sides of the light-emitting layer. Each control circuit regulates the brightness of the corresponding emitted light by adjusting the current intensity flowing through the light-emitting layer. The control circuits can also control the corresponding light-emitting layer not to emit light as required. When the control circuits control the corresponding light-emitting layers not to emit light, the light colors of the light-emitting structure will be formed by the color emitted by the light-emitting layers. In this embodiment, the number of control circuits may be less than or equal to the number of light-emitting layers. For example, in the schematic diagram of the fourth light-emitting structure as shown in FIG. 4, when the control circuit 81 connects the two layers of light-emitting layer 31 and 32, the control circuit 81 will adjust the light extraction of the two layers of light-emitting layer 31 and 32 to change at the same time, and the light color emitted by the two layers of light-emitting layers 31 and 32 is relatively stable. A plurality of control circuits are used to adjust a plurality of light-emitting layers to emit light with different brightness. The light with different colors and brightness passes through the transparent electrodes and mix to form the light with desired color.

In a specific embodiment, the control circuit is arranged in one-to-one correspondence with the light-emitting layers, so as to realize the independent control of the luminous brightness of each light-emitting layer, thereby adjusting the light color of the light-emitting structure flexibly.

In a specific embodiment, the light transmittance of the transparent electrode is 50% to 99.9%, so as to facilitate the effective convergence of the light energy emitted by the adjacent light-emitting layers, thereby producing the desired light color. If the light transmittance of the transparent electrode is too low, it will be unfavorable for the mixing of light of different colors emitted by the adjacent light-emitting layers.

In a specific embodiment, the thickness of the transparent electrode is 10 nm to 100 μm. If the transparent electrode is too thin, it will be easily broken down by the current, which will damage the light-emitting layer, and may also cause leakage current, which will affect the performance of the device. If the transparent electrode is too thick, the light transmittance will be affected, and if it is too thin, the surface impedance will be too large and the conductivity will be affected.

In a specific embodiment, the light-emitting layer is an organic light-emitting layer or a quantum dot light-emitting layer, and the light-emitting layer can also be a stacked organic light-emitting layer and a quantum dot light-emitting layer; preferably the light-emitting layer is a quantum dot light-emitting layer. The selection of the specific materials of the light-emitting layer is not particularly limited, and any organic light-emitting materials and quantum dot materials known in the art can be used, as long as the organic light-emitting materials and quantum dot materials can convert electrical signals into optical signals and meet the light emission requirements. Each layer of the light-emitting structure who has a quantum dot light-emitting layer as the light-emitting layer can be prepared by a solution method, then a stable and excellent light-emitting structure can be obtained by the simple solution method.

In a specific embodiment, the materials of the transparent electrode include at least one of one-dimensional nanomaterials, two-dimensional nanomaterials, metal materials and conductive metal oxide materials.

It can be understood that one-dimensional nanomaterials refer to materials in which one of the three dimensions is not between 0.1 and 100 nm in size, such as silver nanowires and silicon dioxide nanowires, where one of the dimensions (length) size is greater than 100 nm, and the size of the other two dimensions is between 0.1 and 100 nm, thus nanowires and carbon nanotubes are one-dimensional nanomaterials. Two-dimensional nanomaterials refer to materials in which two of the three dimensions are not between 0.1 and 100 nm, such as graphene, where two dimensions (such as length and width) are larger than 100 nm, and the other one dimension (thickness or height) is between 0.1 and 100 nm, thus graphene is two-dimensional nanomaterials. The metal materials in this disclosure mainly refer to metal materials with electrical conductivity other than nanomaterials, and the metal oxide materials in this disclosure mainly refer to metal oxide materials with electrical conductivity other than nanomaterials.

Among them, the appropriate thicknesses of the transparent electrodes are selected according to the different materials used. For example, when one-dimensional nanomaterials or two-dimensional nanoparticle materials are used as the transparent electrode, the thickness of the transparent electrode is between 100 nm and 300 nm; when metal materials are used as the transparent electrode, the thickness of the transparent electrode is between 10 nm and 20 nm; and when conductive metal oxide materials are used as the transparent electrode, the thickness of the transparent electrode is between 10 nm and 100 μm. This disclosure can use transparent electrode materials of different thicknesses, as long as these transparent electrode materials can meet the requirements of the light transmittance of the transparent electrodes.

In a specific embodiment, the materials of the transparent electrode is selected from one or more of silver nanowires, copper nanowires, silver, graphene, indium tin oxide, element-doped zinc oxide and carbon nanotubes. The transparent electrodes formed by these materials have high light transmittance, high conductivity and low surface impedance. For example, the light transmittance of the transparent electrode is 50% to 99.9%, the conductivity can reach 1000 S/m, and the surface impedance of the transparent electrode is less than 50 Ω/sq.

In a more preferred embodiment, the light-emitting structure includes an adhesive layer and two anodes or cathodes which are located on the two opposite surfaces of the adhesive layer. The materials of the two anodes or cathodes are selected from nanowires, and the nanowires of part of each anode or cathode can embedded in the adhesive layer. With the help of the adhesive layer, the anodes or cathodes have better smoothness and light transmittance than those without an adhesive layer, thus forming a light-emitting structure with better overall electrical and optical properties.

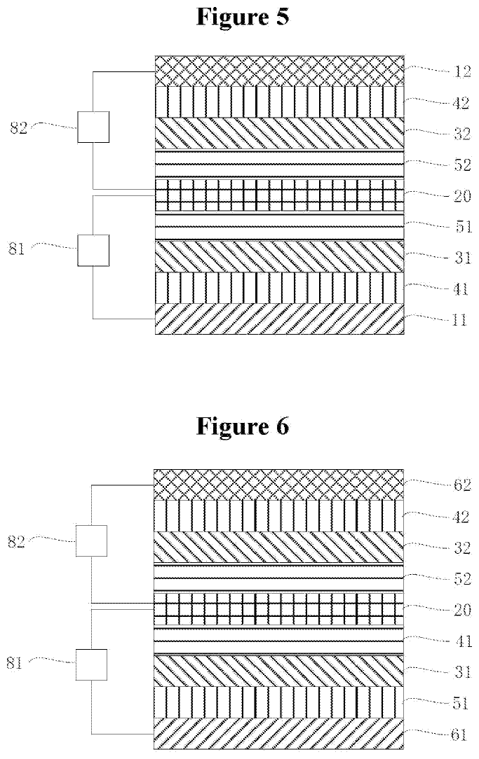

In a specific embodiment, the light-emitting structure includes two layers of light-emitting layers, and the two layers of light-emitting layers can emit blue light and yellow light, respectively, or the two layers of light-emitting layers can emit blue light and green light, respectively, or the two layers of light-emitting layers can emit red light and blue light, respectively, or the two layers of light-emitting layers can emit green light and red light, respectively, and the order of the two layers of light-emitting layers is not limited in this disclosure. The schematic diagram of the fifth light-emitting structure in FIG. 5 can be referred for details. The light-emitting structure may sequentially include a first anode 11, a first hole transport layer 41, a first light-emitting layer 31, a first electron transport layer 51, a transparent electrode 20, a second electron transport layer 52, a second light-emitting layer 32, a second hole transport layer 42 and a second anode 12 as well as control circuits 81, 82. In addition to the functional layers mentioned above, the light-emitting structure may also include other functional layers such as an electron blocking layer, a hole injection layer, an electron injection layer, an intermediate insulating layer, etc., which are not limited in this disclosure, as long as the electroluminescence requirements of the light-emitting structure can be satisfied.

In a more preferred embodiment, the light transmittance of at least one of the first anode 11 and the second anode 12 of the light-emitting structure is 50% to 99.9%. In one embodiment, the light transmittance of the first anode 11 of the light-emitting structure is 50% to 99.9%, and the light transmittance of the second anode 12 is less than 50%, then the light-emitting direction is the direction of the second anode 12 towards the first anode; in another embodiment, the light transmittance of both the first anode and the second anode of the light-emitting structure is 50% to 99.9%, then the light-emitting structure emits bidirectional light output.

In a specific embodiment, the light-emitting structure includes two layers of light-emitting layers, as shown in the schematic diagram of the sixth light-emitting structure in FIG. 6, the light-emitting structure may also sequentially include a first cathode 61, a first electron transport layer 51, a first light-emitting layer 31, a first hole transport layer 41, a transparent electrode 20, a second hole transport layer 52, a second light-emitting layer 32, a second electron transport layer 42 and a second cathode 62, as well as control circuits 81, 82. In addition to the functional layers mentioned above, the light-emitting structure may also include other functional layers such as an electron blocking layer, a hole injection layer, an electron injection layer, and an intermediate insulating layer, etc., which are not limited in this disclosure, as long as the electroluminescence requirements of the light-emitting structure can be satisfied.

In a more preferred embodiment, the light transmittance of at least one of the first cathode 61 and the second cathode 62 of the light-emitting structure is 50% to 99.9%. For example, the light transmittance of the first cathode 61 of the light-emitting structure is 85% and the light transmittance of the second cathode 62 is 30%, then the light-emitting direction is the direction of the second cathode 62 towards the first cathode 61; or it may also be the fact that the light transmittance of both the first cathode 61 and the second cathode 62 of the light-emitting structure is 75%, then the light-emitting structure is a bidirectional light-emitting structure.

In a more preferred embodiment, the materials of the first anode 11 and the second anode 12, or, the materials of the first cathode 61 and the second cathode 62 are independently selected from at least one of one-dimensional nanomaterials, two-dimensional nanomaterials, metal materials and conductive metal oxide materials. More specifically, the materials of the first anode 11 and the second anode 12, or, of the first cathode 61 and the second cathode 62 are independently selected from one or more of silver nanowires, copper nanowires, silver, graphene, indium tin oxide, element-doped zinc oxide and carbon nanotubes.

The transparent electrode is located between the first light-emitting layer 31 and the second light-emitting layer 33. As the shared cathode or the shared anode of the first light-emitting layer 31 and the second light-emitting layer 32, the transparent electrode provides electrons or holes to the first light-emitting layer 31 and the second light-emitting layer 32 on both sides, so as to realize the effective injection of carriers, improving the luminous efficiency and brightness of the first light-emitting layer 31 and the second light-emitting layer 32, and facilitating the regulation of the mixing ratio of blue light and yellow light, so as to obtain the desired light color.

In a specific embodiment, the first light emitting layer 31 emits blue light, the second light emitting layer 32 emits yellow light, the materials of the first light emitting layer 31 is blue quantum dots, and the materials of the second light emitting layer 32 is yellow quantum dots or red-green hybrid quantum dots. After the light emitted by the two layers of light-emitting layers is mixed, white light and light of other colors can be observed. If it is needed to observe a monochromatic light, it is only necessary to turn off the control circuit of the light-emitting layer emitting another color.

In a specific embodiment, the first light emitting layer 31 emits red light and the second light emitting layer 32 emits blue light; Alternatively, the first light emitting layer 31 emits blue light and the second light emitting layer 32 emits green light; Alternatively, the first light emitting layer 31 emits blue light and the second light emitting layer 32 emits red light. After the light emitted by the two layers of light-emitting layers is mixed, the light of the desired color can be observed. If it is needed to observe a monochromatic light, it is only necessary to turn off the control circuit of the light-emitting layer emitting another color. For example, when the first light-emitting layer 31 emits red light and the second light-emitting layer 32 emits blue light, in order to observe the blue light, the control circuit 81 of the first light-emitting layer 31 can be turned off and the control circuit of the second light-emitting layer 32 can be turned on.

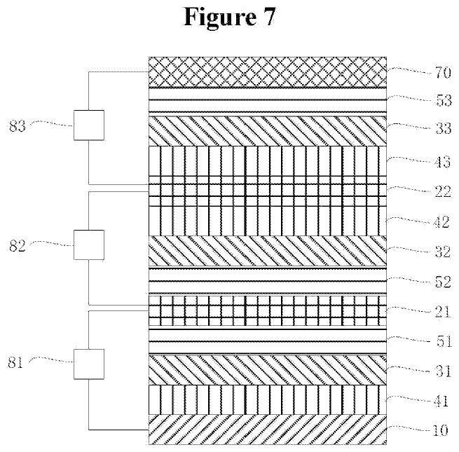

In a specific embodiment, the light-emitting structure includes three layers of light-emitting layers, which emit red light, green light and blue light, respectively. The schematic diagram of the seventh light-emitting structure in FIG. 7 can be referred specifically. The light-emitting structure may successively include an anode 10, a first hole transport layer 41, a first light-emitting layer 31, a first electron transport layer 51, a first transparent electrode 21, a second electron transport layer 52, a second light-emitting layer 32, a second hole transport layer 42, a second transparent electrode 22, a third hole transport layer 43, a third light-emitting layer 33, a third electron transport layer 53 and a cathode 70, as well as control circuits 81, 82, 83. In addition to the above functional layers, the light-emitting structure may also include other functional layers such as an electron blocking layer, a hole injection layer, an electron injection layer, and an intermediate insulating layer, etc., which are not limited in this disclosure, as long as the electroluminescence requirements of the light-emitting structure can be satisfied. The three layers of light-emitting layers described above emit red light, green light and blue light, respectively, and the order of the three layers of light-emitting layers is not limited. After the three lights are mixed, the light of the desired color can be observed. If it is needed to observe a monochromatic light, it is only necessary to turn off the control circuit of the light-emitting layer emitting the other two colors of light.

The first transparent electrode 21 is located between the first light-emitting layer 31 and the second light-emitting layer 32. As the shared cathode of the first light-emitting layer 31 and the second light-emitting layer 32, the first transparent electrode 21 can provide electrons to the first light-emitting layer 31 and the second light-emitting layer 32 on both sides, respectively to realize the effective injection of electrons. The second transparent electrode 22 is located between the second light-emitting layer 32 and the third light-emitting layer 33. As the shared anode of the second light-emitting layer 32 and the third light-emitting layer 33, the second transparent electrode 22 can provide holes to the second light-emitting layer 32 and the third light-emitting layer 33 on both sides, respectively to realize the effective injection of holes. The first transparent electrode 21 and the second transparent electrode 22 effectively improve the luminous efficiency and brightness of the first light-emitting layer 31, the second light-emitting layer 32 and the third light-emitting layer 33, which is conducive to regulating the mixing ratio of red light, green light and blue light, so as to obtain the desired light color.

In a more preferred embodiment, the light transmittance of at least one of the anode 10 and the cathode 70 of the light-emitting structure is 50% to 99.9%, for example, the light transmittance of the cathode 70 of the light-emitting structure is 85% and the light transmittance of the anode 10 is 20%, then the light emitting direction is the direction from the anode 10 to the cathode 70; it may also be the fact that the light transmittance of both the anode 10 and the cathode 70 of the light-emitting structure is 70%, then the light-emitting structure is a bidirectional light-emitting structure.

In a more preferred embodiment, the materials of anode 10 and cathode 70 are independently selected from at least one of one-dimensional nanomaterials, two-dimensional nanomaterials, metal materials and conductive metal oxide materials, respectively. More specifically, the materials of anode 10 and cathode 70 are independently selected from one or more of silver nanowires, copper nanowires, silver, graphene, indium tin oxide, carbon nanotubes, fluorine-doped tin oxide, indium zinc oxide, aluminum-doped zinc oxide, stibium-doped zinc oxide, gallium-doped zinc oxide, cadmium-doped zinc oxide, copper indium oxide, tin oxide, zirconia, aluminum, calcium and barium, etc., but are not limited thereto.

The materials of the hole injection layer of this disclosure is not particularly limited. Any hole injection materials known in the art can be selected according to the actual situations, such as one or more of poly(3,4-ethylenedioxythiophene)-polystyrene sulfonic acid, copper phthalocyanine, 2,3,5,6-tetrafluoro-7,7′,8,8′-tetrahydroquinone dipivaloylmethane, 2,3,6,7,10,11-hexacyano-1,4,5,8,9,12-hexaazabenzophenanthrene, polythienothiophene doped with poly (perfluoroethylene perfluoroether sulfonic acid), MoO₃, VO₂, WO₃, CrO₃, CuO, MoS₂, MoSe₂, WS₂, WSe₂, CuS, etc., but are not limited thereto.

[63] The materials of the hole transport layer 41 of this disclosure is not particularly limited. Any hole transport materials known in the art can be selected according to the actual situations, such as one or more of poly(9,9-dioctylfluorene-CO—N-(4-butylphenyl)diphenylamine), polyvinyl carbazole, poly(N,N′bis (4-butylphenyl)-N,N′-bis (phenyl) diphenylamine), poly(9,9-dioctylfluorene-co-bis-N,N-phenyl-1,4-phenylenediamine), 4,4′,4″-tris (carbazole-9-yl)aniline, 4,4′-bis(9-carbazole)biphenyl, N,N′-diphenyl-N,N′-bis(3-methylphenyl)-1,1′-biphenyl-4,4′-diamine and N,N′-diphenyl-N,N′(1-naphthyl)-1,1′-biphenyl-4,4′-diamine, etc., but are not limited thereto.

The materials of the electron transport layer 51 of this disclosure is not particularly limited. Any electron transport materials known in the art can be selected according to the actual situations, such as one or more of ZnO, TiO₂, SnO₂, Ta₂O₃, InSnO, Alq₃, Ca, Ba, CsF, LiF and CsCO, but are not limited thereto.

This disclosure also provides a display apparatus, the display apparatus includes the light-emitting structure described above, the light-emitting structure includes at least two light-emitting layers stacked layer by layer, which are used to emit light of at least two colors; and a transparent electrode, which is disposed between the adjacent light-emitting layers. The display apparatus includes, but is not limited to, devices or components such as mobile phones, computers, vehicle displays, AR displays, VR displays, smart watches, display screens, and display panels, etc. For example, the components can be electroluminescent devices such as QLED devices, OLED devices, PLED devices, Micro-LED devices and Mini-LED devices, etc. Compared with OLED devices, the light-emitting structure provided in the disclosure is more suitable for QLED devices. The display apparatus of this disclosure can be a top light-emitting display apparatus, or a bottom light-emitting display apparatus, or a transparent display apparatus. Using the light-emitting structure of this disclosure, when the resolution of the display apparatus which emits the superimposed light of red light, green light and blue light is compared with the display apparatus with AGB pixels arranged side by side, the resolution of the display apparatus of this disclosure is increased by 3 times, and the light color can be adjusted flexibly.

This disclosure also provides an illuminating apparatus, the illuminating apparatus includes the light-emitting structure described above, the light-emitting structure includes at least two layers of stacked light-emitting layers, which are used to emit light of at least two colors; and a transparent electrode, which is disposed between the adjacent light-emitting layers. The light-emitting structure is conducive to improving the light output stability of the illuminating apparatus and effectively regulating various light colors.

Although the inventor has described and enumerated the technical solutions of the present disclosure in more detail, it should be understood that it is obvious to those skilled in the art to make modifications and/or changes to the above-mentioned embodiments or to adopt equivalent alternatives without departing from the essence of the spirit of this disclosure, the terms appearing in this disclosure are used for the elaboration and understanding of the technical solutions of this disclosure, and shall not constitute a limitation thereto.

What is claimed is:

1. A light-emitting structure, wherein the light-emitting structure comprising:
at least two light-emitting layers stacked layer by layer, wherein the at least two light-emitting layers are used to emit light of at least two colors; and
a transparent electrode, which is disposed between the adjacent light-emitting layers.

2. The light-emitting structure according to claim 1, wherein the transparent electrode is a shared cathode or a shared anode of the adjacent light-emitting layers.

3. The light-emitting structure according to claim 2, wherein the transparent electrode comprising two transparent electrodes which are anodes and/or cathodes of the adjacent light-emitting layers, respectively;
preferably, a spacer is set between the two transparent electrodes;
more preferably, the spacer comprising a transparent adhesive layer and/or a gas area.

4. The light-emitting structure according to claim 2, wherein the light-emitting structure further comprising at least two control circuits, which are electrically connected with the light-emitting layers;
preferably, the control circuits are arranged in one-to-one correspondence with the light-emitting layers.

5. The light-emitting structure according to claim 1, wherein the light transmittance of the transparent electrode is 50% to 99.9%;
preferably, the thickness of the transparent electrode is 10 nm to 100 μm;
preferably, the light-emitting layer is an organic light-emitting layer and/or a quantum dot light-emitting layer.

6. The light-emitting structure according to claim 5, wherein the materials of the transparent electrode comprising at least one of one-dimensional nanomaterials, two-dimensional nanomaterials, metal materials and conductive metal oxide materials;
preferably, the material of the transparent electrode is selected from one or more of silver nanowires, copper nanowires, silver, graphene, indium tin oxide, element-doped zinc oxide and carbon nanotubes.

7. The light-emitting structure according to claim 5, wherein the light-emitting structure comprising two layers of the light-emitting layers, the two layers of the light-emitting layers emitting red light and green light, respectively, or the two layers of the light-emitting layers emitting red light and blue light, respectively, or the two layers of the light-emitting layers emitting green light and blue light, respectively, or the two layers of the light-emitting layers emitting blue light and yellow light, respectively;
preferably, the light-emitting structure comprising a first electrode, a first hole transport layer, a first light-emitting layer, a first electron transport layer, a transparent electrode, a second electron transport layer, a second light-emitting layer, a second hole transport layer and a second electrode;
more preferably, at least one of the light transmittances of the first electrode and the second electrode is 50% to 99.9%;
more preferably, the materials of the first electrode and the second electrode are independently selected from at least one of one-dimensional nanomaterials, two-dimensional nanomaterials, metal materials and conductive metal oxide materials.

8. The light-emitting structure according to claim 1, wherein the light-emitting structure comprising three layers of the light-emitting layers, which emitting red light, green light and blue light, respectively;
preferably, the light-emitting structure comprising a first electrode, a first hole transport layer, a first light-emitting layer, a first electron transport layer, a first transparent electrode, a second electron transport layer, a second light-emitting layer, a second hole transport layer, a second transparent electrode, a third hole transport layer, a third light-emitting layer, a third electron transport layer and a third electrode;
more preferably, at least one of the light transmittances of the first electrode and the third electrode is 50% to 99.9%;
more preferably, the materials of the first electrode and the third electrode are independently selected from at least one of one-dimensional nanomaterials, two-dimensional nanomaterials, metal materials and conductive metal oxide materials.

9. The light-emitting structure according to claim 1, wherein each of the transparent electrodes located between the adjacent light-emitting layers comprising a transparent electrode I and a transparent electrode II, and the transparent electrode I and the transparent electrode II each independently serve as an anode or a cathode of the light-emitting layer adjacent thereto;
preferably, a spacer is arranged between the transparent electrode I and the transparent electrode II;
more preferably, the spacer comprising a transparent adhesive layer and/or a gas area.

10. A display apparatus, wherein it comprising the light-emitting structure according to claim 1.

11. An illuminating apparatus, wherein it comprising the light-emitting structure according to claim 1.

12. The light-emitting structure according to claim 2, wherein the transparent electrode comprising two transparent electrodes which are anodes and/or cathodes of the adjacent light-emitting layers, respectively;
a transparent adhesive layer is set between the two transparent electrodes; and
the materials of the transparent electrode are one-dimensional nanomaterials.

13. The light-emitting structure according to claim 12, wherein the light-emitting structure further comprising at least two control circuits, which are electrically connected with the light-emitting layers;
preferably, the control circuits are arranged in one-to-one correspondence with the light-emitting layers.

14. The light-emitting structure according to claim 12, wherein the light transmittance of the transparent electrode is 50% to 99.9%;
preferably, the thickness of the transparent electrode is 10 nm to 100 μm;
preferably, the light-emitting layer is an organic light-emitting layer and/or a quantum dot light-emitting layer.

15. The light-emitting structure according to claim 12, wherein the materials of the transparent electrode also comprising at least one of two-dimensional nanomaterials, metal materials and conductive metal oxide materials;
preferably, the material of the transparent electrode is selected from one or more of silver nanowires, copper nanowires, silver, graphene, indium tin oxide, element-doped zinc oxide and carbon nanotubes.

16. The light-emitting structure according to claim 12, wherein the light-emitting structure comprising two layers of the light-emitting layers, the two layers of the light-emitting layers emitting red light and green light, respectively, or the two layers of the light-emitting layers emitting red light and blue light, respectively, or the two layers of the light-emitting layers emitting green light and blue light, respectively, or the two layers of the light-emitting layers emitting blue light and yellow light, respectively;
preferably, the light-emitting structure comprising a first electrode, a first hole transport layer, a first light-emitting layer, a first electron transport layer, a transparent electrode, a second electron transport layer, a second light-emitting layer, a second hole transport layer and a second electrode;
more preferably, at least one of the light transmittances of the first electrode and the second electrode is 50% to 99.9%;
more preferably, the materials of the first electrode and the second electrode are independently selected from at least one of one-dimensional nanomaterials, two-dimensional nanomaterials, metal materials and conductive metal oxide materials.

17. The light-emitting structure according to claim 12, wherein the light-emitting structure comprising three layers of the light-emitting layers, which emitting red light, green light and blue light, respectively;
preferably, the light-emitting structure comprising a first electrode, a first hole transport layer, a first light-emitting layer, a first electron transport layer, a first transparent electrode, a second electron transport layer, a second light-emitting layer, a second hole transport layer, a second transparent electrode, a third hole transport layer, a third light-emitting layer, a third electron transport layer and a third electrode;
more preferably, at least one of the light transmittances of the first electrode and the third electrode is 50% to 99.9%;
more preferably, the materials of the first electrode and the third electrode are independently selected from at least one of one-dimensional nanomaterials, two-dimensional nanomaterials, metal materials and conductive metal oxide materials.

18. The light-emitting structure according to claim 12, wherein each of the transparent electrodes located between the adjacent light-emitting layers comprising a transparent electrode I and a transparent electrode II, and the transparent electrode I and the transparent electrode II each independently serve as an anode or a cathode of the light-emitting layer adjacent thereto;
preferably, a spacer is arranged between the transparent electrode I and the transparent electrode II;
more preferably, the spacer comprising a transparent adhesive layer and/or a gas area.

19. The light-emitting structure according to claim 1, wherein the light-emitting layer is a quantum dot light-emitting layer.

20. The light-emitting structure according to claim 12, wherein the light-emitting layer is a quantum dot light-emitting layer.
